(19) United States
(12) Patent Application Publication
(10) Pub. No.: US 2008/0083966 A1
(43) Pub. Date: Apr. 10, 2008

(54) Schottky barrier semiconductor device

(75) Inventor: Kazuhiro Oonishi, Osaka (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/878,291

(22) Filed: Jul. 23, 2007

(30) Foreign Application Priority Data
Jul. 28, 2006 (JP) 2006-205465

(51) Int. Cl. H01L 29/47

(52) U.S. Cl. 257/475; 257/E29.148

(57) ABSTRACT

The present invention provides a Schottky barrier semiconductor device having a semiconductor substrate 101, a low-concentration semiconductor layer 102, trenches 103 formed in the low-concentration semiconductor layer 102 and extending to the semiconductor substrate 101, and a mesa portion 102a formed between the trenches 103. This provides a high durability against a surge or transient voltage.

### FIELD OF THE INVENTION

The present invention relates to a Schottky barrier semiconductor device, and specifically, to a technique for a semiconductor device having a Schottky junction.

### BACKGROUND OF THE INVENTION

A Schottky barrier semiconductor device exerts a rectifying effect and is applicable to a wide range of fields as shown in FIG. 23. In general, a rectifier must offer a low resistance to a forward current, while offering a very high resistance to a backward current. The rectifying effect of the Schottky barrier semiconductor device is based on transportation of a nonlinear, unipolar charge carrier (current) crossing an interface in a metal/semiconductor junction. This makes it possible to provide a large forward current with a reduced loss. Thus, the Schottky barrier semiconductor device is widely used as an output rectifier particularly for mode switching power sources such as motor driving mechanisms and high-speed power switching apparatuses.

The transportation of the unipolar charge carrier (current) crossing the interface in the metal/semiconductor junction in the Schottky barrier semiconductor device basically involves the following plural processes.

(1) Transportation of electrons from the semiconductor to the metal beyond a potential barrier between the metal and the semiconductor (thermoelectronic emission)

In general, at the room temperature (for example, 300 K) the main current flowing through the Schottky barrier semiconductor device (for example, silicon (Si), having a semiconductor impurity concentration of 1×10¹⁶ cm⁻³) is a thermoelectronic emission current.

(2) Quantum-mechanical tunneling of electrons through the potential barrier between the metal and the semiconductor (field emission)

In the Schottky barrier semiconductor device, a relatively wide potential barrier is present between the metal and the semiconductor and limits the tunneling current.

(3) Recoupling in a depletion region in the semiconductor

A recoupling current in the depletion region is similar to one observed in a PN junction diode and is taken into account only for a very low forward current concentration.

(4) Injection of holes from the metal into the semiconductor

A minority carrier injection current is taken into account only for a high forward current concentration.

(5) Interface current resulting from interface trap between the metal and the semiconductor and edge leakage current resulting from the concentration of electric fields in a peripheral portion in contact with the metal

In recent years, efforts have been made to reduce the voltage and power consumption of power supply apparatuses. Schottky barrier semiconductor devices with a reduced power loss have been desired. Thus, a Schottky barrier semiconductor device is required which has a large forward current, a low forward voltage drop, a high backward stopping voltage, and a small backward leakage current.

The forward voltage drop in the Schottky barrier semiconductor device depends on a forward voltage drop in the metal/semiconductor junction and the series resistance components of a semiconductor region and other regions.

Consequently, a reduction in forward power loss requires a reduction in series resistance component. The reduction in series resistance component requires an increase in the concentration of impurities in the semiconductor layer and a reduction in the thickness of the semiconductor layer.

On the other hand, to increase the backward stopping voltage to reduce the backward leakage current, it is necessary to avoid excessive reverse bias fields at the interface in the metal/semiconductor junction. To achieve this, the impurity concentration of the semiconductor layer is reduced to increase the thickness thereof.

The magnitude of the backward leakage current is inverse proportional to the height of the Schottky barrier (potential barrier) between the metal and the semiconductor. The magnitude of the forward voltage drop is proportional to the height of the Schottky barrier. The height of the Schottky barrier varies in inverse proportion to the concentration of impurities in the semiconductor layer. Thus, a reduction in forward voltage drop increases the backward leakage current, while reducing a backward breakdown voltage owing to collision ionization.

As described above, for the Schottky barrier semiconductor device, there is a tradeoff relationship between the forward voltage drop and the backward leakage current. This makes it difficult to simultaneously minimize both of these properties. Thus, in designing the Schottky barrier semiconductor device, not all device parasitic values can be simultaneously minimized. Consequently, design parameters such as the height of the Schottky barrier, the concentration of impurities in the semiconductor layer, and the thickness of the semiconductor layer are designed to meet requirements for a particular application.

For example, the height of the Schottky barrier is designed to be smaller for high current operation applications, that is, applications for which a forward power loss is important. In contrast, the height of the Schottky barrier is designed to be greater for applications in which the Schottky barrier semiconductor device is used in an atmosphere with a high ambient temperature or applications with a high stopping voltage.

The height of the Schottky barrier formed of the metal/semiconductor junction is determined by the potential difference in a work function between the metal and the semiconductor.

As shown in Formula (1), the forward voltage drop (VF) depends on a saturated current (Js) that is a function of the height (φbn) of the Schottky barrier, the resistances (Rd, Rs, and Rc) of a drift region, a substrate, and a contactor, and a forward current density (JF).
VF=kT/q×ln(JF/Js)+(Rd+Rs+Rc)JF (1)

The maximum stopping voltage (BVpp) of a Schottky barrier semiconductor device having a one-sided abrupt junction structure is theoretically equal to the breakdown voltage of an ideal parallel-plane PN junction semiconductor device (for example, P+/N or N+/P). As described in Formula (2), the breakdown voltage (BVpp) depends on the concentration of impurities in the drift region (Nd).
Nc=2×10¹⁸(BVpp)− 4/3 (2)

FIG. 22 shows the breakdown voltage and depletion region width vs. the concentration of impurities in the drift region for the ideal parallel-plane PN junction semiconductor device. However, the breakdown voltage of the actual Schottky barrier semiconductor device is about one-third of that shown in FIG. 22. The breakdown voltage is reduced by the degraded potential barrier resulting from electric fields applied to between the metal and semiconductor as well as the tunneling current.

One structure that overcomes the tradeoff between the forward voltage drop and backward stopping voltage in the Schottky barrier semiconductor device is a Schottky barrier semiconductor device controlled by a PN junction (Junction Barrier Schottky (JBS)).

The JBS has an arrangement of Schottky junctions on a front surface of the semiconductor substrate, and a corresponding semiconductor drift region under the Schottky junctions. The JBS has a PN junction lattice with its pieces dotted among the Schottky junctions and is called a pinch semiconductor device because of the effects of the PN junction lattices.

That is, the depletion region, extending from the PN junction lattice to the drift region, does not pinch off the drift region during the application of a forward voltage. The depletion region pinches off the drift region during the application of a backward voltage. In general, when the backward voltage reaches a threshold of several volts, the depletion region pinches off the drift region. The size of the PN junction lattice and the concentration of impurities in the P-type region are designed so as to exert the above effect. Consequently, when the backward voltage reaches the threshold, the depletion region prevents the application of a voltage to the Schottky barrier. This inhibits an increase in backward leakage current.

FIG. 21 is a sectional view of the JBS. The JBS includes an N-type semiconductor substrate 301, an N-type semiconductor layer 302 formed on one major surface (front surface) of the N-type semiconductor substrate 301, P-type semiconductor layers 305 formed at upper positions in the N-type semiconductor layer 302 at predetermined intervals, a front surface electrode 303 formed on the N-type semiconductor layer 302 and P-type semiconductor layers 305, and a back surface electrode 307 formed on the other major surface (back surface) of the N-type semiconductor substrate 301.

In this configuration, the JBS has a plurality of Schottky junctions 304 and a PN junction lattice 306. Each of the Schottky junctions 304 is formed of the N-type semiconductor layer 302 and the front surface electrode 303. The PN junction lattice 306 is formed of the P-type semiconductor layers 305 and the N-type semiconductor layer 302.

However, the JBS commonly undergoes a great forward voltage drop. This is because the JBS offers a relatively great series resistance and has a reduced area ratio of the Schottky junction region. The decrease in the area ratio of the Schottky junction region necessarily results from the presence of the PN junction lattice all over the front surface of the semiconductor.

Moreover, an increase in forward current starts the transmission of minority carriers under the effect of the PN junction. This reduces the power efficiency in high frequency regions.

The backward stopping voltage in the JBS is higher than that in a junction barrier Schottky having a comparable concentration of impurities in the drift region. However, the stopping voltage in the JBS cannot exceed a backward stopping voltage in the parallel-plane PN junction shown in FIG. 22, for an essential reason.

Another structure overcoming the tradeoff between the forward voltage drop and the backward stopping voltage is a Schottky barrier semiconductor device having MOS trenches (Trench MOS Barrier Schottky (TMBS)). The structure has a breakdown voltage higher than the theoretical breakdown voltage of the ideal parallel-plane PN junction.

The structure is shown in FIG. 20. The TMBS has an N-type semiconductor layer 402 formed on one major surface (front surface) of an N-type semiconductor substrate 401, a plurality of trenches 403 formed at upper positions in the N-type semiconductor layer 402, and a mesa portion 402a located between the trenches 403 and constituting an active portion (drift region).

An insulating film 404 is formed at the boundary between the mesa portion 402a and the trench 403. A first electrode 405 is formed inside the trench 403, surrounded by the insulating film 404. A second electrode 406 is provided on the N-type semiconductor layer 402 to form a Schottky junction. The first electrode 405 and the second electrode 406 form an ohmic junction. A third electrode 407 is formed on the other major surface (back surface) of the N-type semiconductor substrate 401.

In this configuration, majority carriers in the mesa portion 402a, constituting a drift region, are charge-coupled to carriers in the first electrode 405. This results in a breakdown voltage higher than that of the ideal parallel-plane PN junction semiconductor device. This charge coupling is due to redistribution of electric fields that occurs under the effect of the Schottky junction.

Moreover, electric fields resulting from the Schottky junction between the N-type semiconductor layer 402 and the second electrode 406 are reduced by the pinch-off of the mesa portion 402a. This enables a reduction in backward leakage current. Further, the absence of PN junctions prevents the possible transmission of minority carriers even when a large current flows forward. This in turn prevents a decrease in power efficiency in high frequency regions.

FIG. 19 shows the relationship between the trench depth and field distribution in the ideal parallel-plane PN junction semiconductor device. The figure shows that a variation in trench depth (“d”) causes electric fields to be redistributed.

For the parallel-plane PN junction semiconductor device, the semiconductor layer has a thickness (drift region) of 3.5 μm, and the drift region has an impurity concentration of 3×10¹⁶ cm⁻³. The mesa portion has a width of 0.5 μm, and the Schottky barrier provides 0.58 eV.

As is apparent from FIG. 19, the charge coupling between the trench MOS electrode and the mesa exerts two effects.

(1) Electric fields in the Schottky junction are reduced.

The field intensity at the Schottky junction interface, that is, at a depth of 0 μm in the drift region, decreases as the trench depth increases. That is, the field intensity at the Schottky junction interface is lower at a trench depth d of 2.4 than at a trench depth d of 0.6.

(2) The peak of the field distribution shifts to the inside of the drift region located away from the Schottky junction.

The peak of the field distribution shifts to a deeper position in the drift region as the trench depth increases: the peak is located at a deeper position at a trench depth d of 2.4 than at a trench depth d of 0.6.

Thus, a reduction in the field intensity at the Schottky junction interface enables a reduction in a backward leakage current resulting from the reduced height of the Schottky barrier. As the peak of the field intensity shifts away from the Schottky junction interface toward a deeper position in the drift region, the breakdown voltage increases above the theoretical breakdown voltage of the parallel-plane PN junction semiconductor device.

FIG. 18 shows the relationship between the trench depth and breakdown voltage in the TMBS shown in FIG. 20. As shown in FIG. 18, when the trench depth has at least a given value, the breakdown voltage does not increase even with an increase in trench depth. This is because in the mesa portion, semiconductor fields reach the theoretical limit on the breakdown voltage beyond which avalanche breakdown occurs.

Increasing the breakdown voltage requires an increase in the concentration of impurities in the mesa portion and that in the field intensity for the avalanche breakdown. However, increasing the impurity concentration makes it difficult to deplete the mesa portion during the application of the backward voltage. This increases the backward leakage current. This in turn results in the tradeoff relationship between the breakdown voltage and the backward leakage current.

Thus, even the above TMBS does not allow the provision of an efficient semiconductor device having a reduced backward leakage current, an increased stopping voltage, a reduced forward voltage drop, and an improved power efficiency.

The Schottky barrier semiconductor device has a reduced durability against a surge or a transient voltage at the interface in the metal/semiconductor junction. The flow of the surge or transient voltage concentrates in a region with a lower backward breakdown voltage. Thus, common Schottky barrier semiconductor devices have a PN junction at a terminal portion of the metal/semiconductor junction interface which junction is called a guard ring and for which junction the breakdown voltage is designed lower than that for the metal/semiconductor junction, so as to enhance the durability against the surge or transient voltage.

In the above TMBS, the breakdown voltage varies depending on the thickness of the insulting film on the trench; the breakdown voltage is lowest at the thinnest part of the insulating film. Thus, if a plurality of trench/mesa structures are formed in one semiconductor device, the surge or transient voltage concentrates in a trench/mesa structure with a lower breakdown voltage. As a result, the semiconductor device has a very low durability against the surge and transient voltage.

The present invention solves these problems. An object of the present invention is to provide an efficient Schottky barrier semiconductor device which has a reduced backward leakage current, an increased stopping voltage, a reduced forward voltage drop, and an improved power efficiency and which has a high durability against the surge and transient voltage.

### DISCLOSURE OF THE INVENTION

To accomplish the object, the present invention provides a Schottky barrier semiconductor device including a semiconductor substrate, a semiconductor layer formed on one major surface of the semiconductor substrate and having a lower impurity concentration than the semiconductor substrate, a plurality of trenches formed in the semiconductor layer so as to extend from a front surface of the layer to the semiconductor substrate, a mesa portion formed between the trenches in the semiconductor layer, an insulating film formed at a boundary between the mesa portion and the trench, a first electrode formed inside the trench surrounded by the insulating film, a second electrode formed on the front surface of the semiconductor layer so as to cover the first electrode and forming a Schottky junction with the semiconductor layer and an ohmic junction with the first electrode, and a third electrode formed on the other major surface of the semiconductor substrate.

The impurity concentration is adjusted at appropriate positions in the semiconductor layer to adjust the intensity of electric fields in the semiconductor layer which is proportional to the impurity concentration. A breakdown voltage in the semiconductor layer is fixed.

The concentration gradient of the impurities in the semiconductor layer varies step by step and increases as the distance from the semiconductor substrate decreases. The breakdown voltage in the semiconductor layer is fixed.

The concentration of impurities in the semiconductor layer is substantially fixed in a region extending at least 1 um from a Schottky junction interface between the second electrode and the semiconductor layer, to the semiconductor substrate.

A depletion region formed around a periphery of the first electrode in the semiconductor layer covers the mesa portion all over the width of the mesa portion between the trenches.

A pair of parallel annular trenches surrounding all the mesa portions and all the trenches is formed in the semiconductor layer. A portion between the annular trenches constitutes a band-like mesa portion. A band-like insulating film is formed along a boundary between each of the annular trenches and the semiconductor layer. A fourth electrode is formed in one of the annular trenches. A fifth electrode is formed in the other annular trench. The band-like mesa portion is made of the semiconductor layer constituting a lower layer portion and a semiconductor layer constituting an upper layer portion and having a conductivity type different from that of the semiconductor layer. The second electrode forms an ohmic junction with the upper semiconductor layer and with the first, fourth, and fifth electrodes. The breakdown voltage at a PN junction between the upper semiconductor layer and lower semiconductor layer of the band-like mesa portion determines the breakdown voltage of the semiconductor device.

The depletion region formed around the periphery of the fourth and fifth electrodes in the semiconductor layer covers the band-like mesa portion all over the width of the mesa portion between the annular trenches.

The second electrode has a recessed and projecting shape at the interface between the second electrode and the semiconductor layer.

The second electrode projects partly into the trench, inside which the insulating film abuts against the second electrode. The Schottky junction between the semiconductor layer and the second electrode is formed around the periphery of the trench.

A terminal portion of the insulating film which abuts against the second electrode inside the trench is tapered.

A high-concentration semiconductor layer is formed so as to extend from the front surface of the low-concentration semiconductor layer to the semiconductor substrate. An insulating film in a front surface portion is formed over the front surfaces of the low-concentration semiconductor layer and the high-concentration semiconductor layer so as to join to the insulating film at the boundary between the trench and the semiconductor layer. A window is formed in the insulating film in the front surface portion located on the front surface of the high-concentration semiconductor layer. A sixth electrode is formed over the window in the high-concentration semiconductor layer.

A seventh electrode is formed so as to extend from the front surface of the low-concentration semiconductor layer to the other major surface of the semiconductor substrate. An insulating film is formed at an electrode boundary between the seventh electrode and the low-concentration semiconductor layer and at an electrode boundary between the seventh electrode and the semiconductor substrate. The seventh electrode and the third electrode form an ohmic junction.

A high-concentration semiconductor layer is formed between the semiconductor substrate and the low-concentration semiconductor layer. A high-concentration semiconductor separation layer is formed so as to extend from the front surface of the low-concentration semiconductor layer to the semiconductor substrate. The low-concentration semiconductor layer and the high-concentration semiconductor layer formed between the semiconductor substrate and the low-concentration semiconductor layer have a conductivity type different from that of the semiconductor substrate. The semiconductor separation layer has the same conductivity type as that of the semiconductor substrate.

The relationship between the ionization rate (α) of electrons in the semiconductor layer and the field intensity (ε) is given by:
α=A×exp(−(b/ε)m) (2)
(for silicon, A=3.8×10⁶ cm⁻¹, b=1.75×10⁶ cm⁻¹, m=1).

When the width of the depletion region in the semiconductor layer is defined as W, the condition under which the semiconductor undergoes avalanche breakdown is expressed by:

$${\int }_{0}^{W} α ⅆ x = 1 \qquad ( 3 )$$

A critical field intensity satisfying Formula (3) varies depending on the concentration of impurities in the semiconductor layer and is proportional to the index of the impurity concentration as shown in FIG. 17. Electric fields in the semiconductor layer are distributively applied in proportion to the concentration gradient of impurities in the semiconductor layer.

The conventional TMBS has a large impurity concentration gradient between the semiconductor substrate and the semiconductor drift layer. Thus, electric fields concentrate between the semiconductor substrate and the semiconductor drift layer. Consequently, a low backward applied voltage makes it possible to reach the critical field intensity, causing avalanche breakdown. This prevents the backward stopping voltage from being increased.

However, in the semiconductor device in accordance with the present invention, to inhibit the concentration of electric fields, the conductive low-concentration semiconductor layer has the reduced impurity concentration gradient. Further, the impurity concentration of the low-concentration semiconductor layer has the predetermined concentration gradient. This allows electric fields in appropriate regions to be distributed to make uniform the voltage at which avalanche breakdown occurs. This makes it possible to provide a high backward stopping voltage.

In the conventional TMBS, if the bottom of the trench does not reach the semiconductor substrate, electric fields concentrate in a part of the trench bottom which has a large curvature. This reduces the breakdown voltage. The conventional TMBS is therefore disadvantageous in that the breakdown voltage of the semiconductor device depends significantly on the shape of the trench bottom.

In the semiconductor device in accordance with the present invention, the trench is formed so as to reach the semiconductor substrate. This avoids applying electric fields to the trench bottom, preventing the breakdown voltage from being varied by the shape or curvature of the trench bottom.

The application of electric fields to the Schottky junction reduces the potential barrier to increase the backward leakage current. In the conventional TMBS, electric fields are also applied to the Schottky junction to increase the backward leakage current.

On the other hand, in the semiconductor device in accordance with the present invention, the concentration of impurities in the low-concentration semiconductor layer is substantially fixed in the region extending at least 1 um from the Schottky junction interface. As shown in FIGS. 16A to 16D, it is possible to avoid applying electric fields to the Schottky junction to reduce the backward leakage current.

In the semiconductor device in accordance with the present invention, the application of the backward voltage forms the depletion region around the periphery of the first electrode. The depletion region covers the entire mesa portion between the first electrodes, causing pinch-off. This enables a further reduction in backward leakage current. The width of the mesa portion in the low-concentration semiconductor layer is designed so as to realize the pinch-off.

As described above, in the conventional TMBS, the surge or transient voltage concentrates in the trench/mesa portion in which the insulating film on the trench is thinnest. The conventional TMBS thus have a very low durability. However, in the semiconductor device in accordance with the present invention, the breakdown voltage of the semiconductor device is determined by the breakdown voltage of the PN junction. This allows a current to flow through the PN junction interface when the surge or transient voltage is applied. The semiconductor device in accordance with the present invention thus has a very high durability against the surge and transient voltage.

The major factor of the forward voltage drop is the resistance component of the semiconductor layer formed on the semiconductor substrate. In the semiconductor device in accordance with the present invention, the depletion region is pinched off during the application of the backward voltage to enable a reduction in electric fields applied to the PN junction. Thus, even with the thickness of the low-concentration semiconductor layer reduced, the breakdown voltage of the PN junction can be maintained. Consequently, with the semiconductor device in accordance with the present invention, by reducing only the thickness of the low-concentration semiconductor layer without a reduction in the backward breakdown voltage, it is possible to reduce the forward voltage drop to improve the power efficiency.

The amount of forward current is proportional to the area of the Schottky junction interface in the semiconductor device. With the conventional TMBS, the chip area of the semiconductor element must be increased in order to increase the area of the Schottky junction interface. However, manufacture costs and limits on a mounting package prevent an increase in the area of the Schottky junction interface. This makes it difficult to increase the amount of forward current.

In the semiconductor device in accordance with the present invention, the second electrode projects partly into the trench. The low-concentration semiconductor layer and the second electrode form the Schottky junction in a part of the trench. This makes it possible to increase the Schottky junction area and thus the amount of forward current without an increase in the chip size of the semiconductor element.

As described above, the Schottky barrier semiconductor device in accordance with the preset invention is efficient because of the reduced backward leakage current, the increased stopping voltage, the reduced forward voltage drop, and the improved power efficiency compared to the conventional TMBS. The Schottky barrier semiconductor device in accordance with the present invention also has a high durability against the surge and transient voltage.

### BRIEF DESCRIPTION OF THE DRAWINGS

FIG. 1 is a sectional view of a semiconductor device in accordance with Embodiment 1 of the present invention;

FIGS. 2A to 2D are comparative diagrams of a depletion region;

FIG. 3 is a comparative diagram of the distribution of electric fields in a depth direction;

FIG. 4 is a comparative diagram of a backward property;

FIG. 5 is a diagram of the correlation between a forward voltage drop and a backward leakage current;

FIG. 6 is a sectional view of a semiconductor device in accordance with Embodiment 2 of the present invention (stepwise concentration gradient type);

FIG. 7 is a sectional view of a semiconductor device in accordance with Embodiment 3 of the present invention (trench type);

FIGS. 8A to 8G are sectional views showing steps of a process of manufacturing a semiconductor device in accordance with the present invention;

FIG. 9 is a diagram showing the shape of an oxide film on a sidewall portion of a trench during the manufacture process;

FIGS. 10A and 10B are a horizontal sectional view and a vertical sectional view showing a semiconductor device in accordance with Embodiment 4 of the present invention (peripheral measures type);

FIG. 11 is a comparative diagram of a variation in breakdown voltage;

FIG. 12 is a comparative diagram of surge resistance;

FIG. 13 is a sectional view of a semiconductor device in accordance with Embodiment 5 of the present invention (flip chip type 1);

FIG. 14 is a sectional view of a semiconductor device in accordance with Embodiment 6 of the present invention (flip chip type 2);

FIG. 15 is a sectional view of a semiconductor device in accordance with Embodiment 7 of the present invention (composite type);

FIGS. 16A to 16D are diagrams of distributions in a depth direction of the semiconductor device in accordance with the present invention;

FIG. 17 is a diagram of the correlation between semiconductor impurity concentration and critical field intensity in the semiconductor device in accordance with the present invention;

FIG. 18 is a diagram of the correlation between trench depth and breakdown voltage in a TMBS;

FIG. 19 is a diagram of the correlation between the distribution of electric fields and the depth direction of the TMBS;

FIG. 20 is a sectional view of the TMBS;

FIG. 21 is a sectional view of a JBS;

FIG. 22 is a diagram showing the breakdown voltage and depletion region width vs. the concentration of impurities in a drift region in an ideal parallel-plane PN junction semiconductor device; and

FIG. 23 is a diagram showing applications of the semiconductor device.

### DESCRIPTION OF THE EMBODIMENTS

Embodiments of the semiconductor device of the present invention will be described below with reference to the drawings.

### Embodiment 1

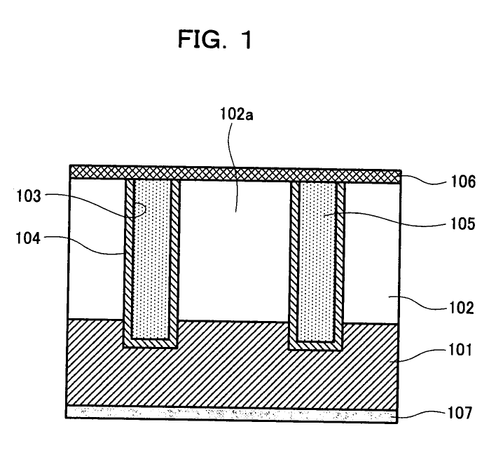

FIG. 1 shows a sectional view of a Schottky barrier semiconductor device in accordance with the present invention. In FIG. 1, the Schottky barrier semiconductor device has a semiconductor layer 102 with a low impurity concentration formed on one of the major surfaces, that is, the front and back surfaces, of a semiconductor substrate 101 of N or P conductivity type. A plurality of trenches 103 are formed in the low-concentration semiconductor layer 102. Each of the trenches 103 is shaped so as to extend from the front surface of the low-concentration semiconductor layer 102 to the semiconductor substrate 101.

A part of the semiconductor layer 102 between the trenches 103 forms a mesa portion 102a. An insulating film 104 is formed at the boundary between the mesa portion 102a and the trench 103. A first electrode 105 is formed inside the trench 103 surrounded by the insulating film 104.

A second electrode 106 is formed on the front surface of the low-concentration semiconductor layer 102 so as to cover the first electrode 105. The second electrode 106 forms a Schottky junction with the semiconductor layer 102 and an ohmic junction with the first electrode 105. A third electrode 107 is formed on the other of the major surfaces, that is, the front and back surfaces, of the semiconductor substrate 101.

The intensity of electric fields inside of the semiconductor layer 102 is proportional to the concentration of impurities at appropriate positions in the layer. Thus, the concentration of impurities at the appropriate positions in the semiconductor layer 102 is adjusted to regulate the field intensity of the semiconductor layer 102, which is proportional to the impurity concentration. This fixes the breakdown voltage of the low-concentration semiconductor layer 102.

In a specific example of the Schottky barrier semiconductor device, the material of the second electrode 106 is Ti, and a Schottky barrier has a height of 0.58 eV. The N-type (or P-type) semiconductor substrate 101 has an impurity concentration of 3×10¹⁹ cm⁻³. The impurities in the low-concentration semiconductor layer 102 have a uniform concentration of 5×10¹⁵ cm⁻³ down to a depth of 1.5 um from the front surface of the semiconductor layer 102. An impurity rising height to which impurities rise from the semiconductor substrate 101 when the semiconductor layer 102 is epitaxially formed is 2 um. The concentration gradient of impurities in a rising region of the semiconductor layer 102 is at most 1×10¹⁹ cm⁻⁴. The semiconductor layer 102 has a thickness of 3.5 um. The mesa portion 102a has a width of 2 um. The trench has a depth of 4 um. The insulating film 104 is a thermal oxide film having a thickness of 2,000 Å. The first electrode 105 is N-type doped polysilicon.

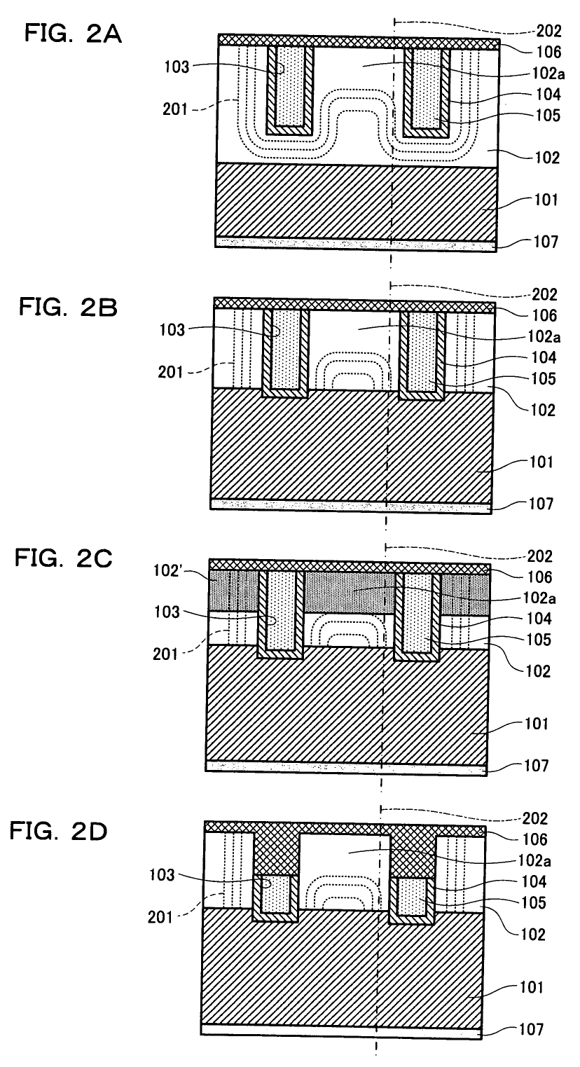

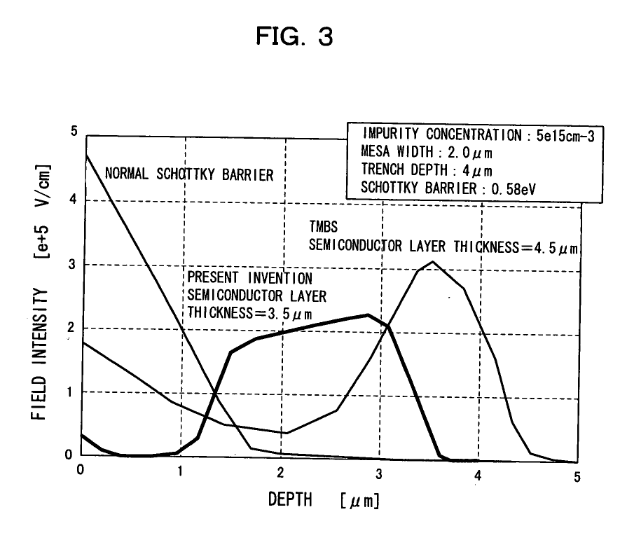

FIG. 2A is shown as a comparative example and shows the shape of a depletion region 201 that is generated in a conventional TMBS structure when the semiconductor layer 102 has a thickness of 4.5 um. FIG. 2B shows the shape of the depletion region 201 that is generated in the Schottky barrier semiconductor device in accordance with the present embodiment when the semiconductor layer 102 has a thickness of 3.5 um. FIG. 3 shows the ratio of field intensity along the position of a dashed line 202 in FIGS. 2A and 2B.

As shown in FIG. 2A, if the trench 103 does not reach the semiconductor substrate 101 and the insulating film 104 lies away from the semiconductor substrate 101, a continuous depletion region 201 is formed around the periphery of the first electrode 105. Rounded corners are formed in the depletion region 201 at a lower end of the trench 103. Electric fields concentrate in the vicinity of the corners. Thus, as shown in FIG. 3, the field intensity exhibits a rapid peak in the depletion region 201 in the vicinity of the lower end of the trench 103.

On the other hand, as shown in FIG. 2B, in the present invention, the trench 103 reaches the semiconductor substrate 101, and the insulating film 104 abuts against the semiconductor substrate 101. Thus, the depletion region 201, lying around the periphery of the first electrode 105, is blocked by the semiconductor substrate 101 and thus discontinuously formed. The depletion region 201 is linearly shaped at the lower end of the trench 103. Consequently, the depletion region 201 has no corners, that is, no elements at which electric fields concentrate. Thus, as shown in FIG. 3, the field intensity is distributed in the depletion region 201 around the periphery of the trench 103 without forming any rapid peak.

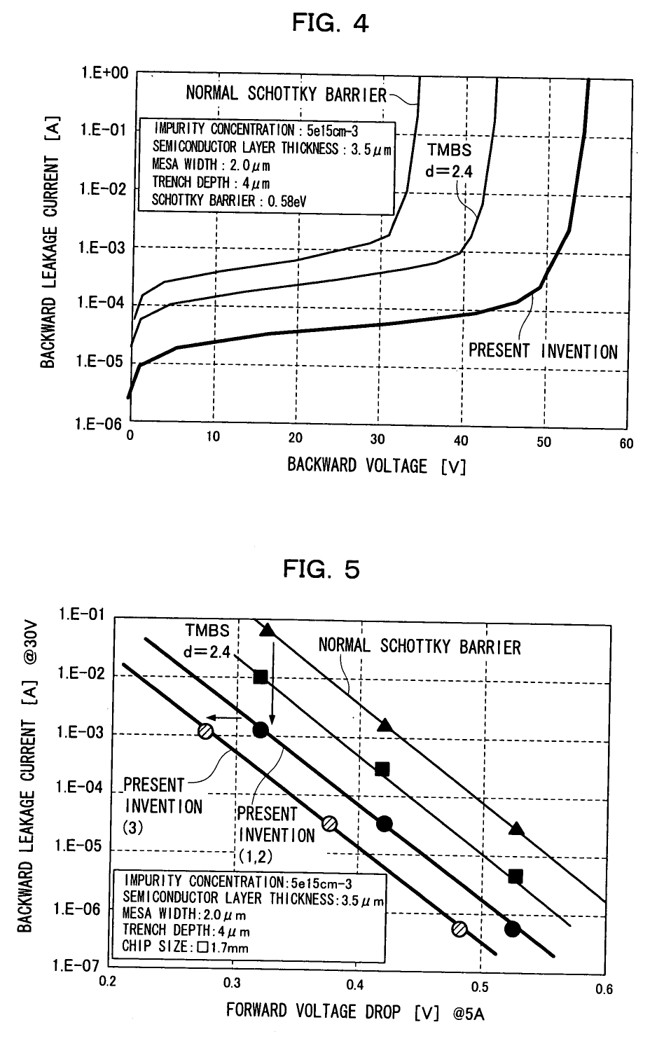

Thus, as shown in FIG. 4, the semiconductor device in accordance with the present invention has a higher breakdown voltage (backward voltage) and a smaller backward leakage current at the same backward voltage than the conventional semiconductor device.

FIG. 5 shows a diagram of the correlation between forward voltage drop and backward leakage current when the material of the second electrode 106 is varied to vary the height of the Schottky barrier in the same construction as described above. As shown in FIG. 5, the semiconductor device in accordance with the present invention has a smaller backward leakage current at the same forward voltage drop than the conventional semiconductor device. This improves the tradeoff relationship.

### Embodiment 2

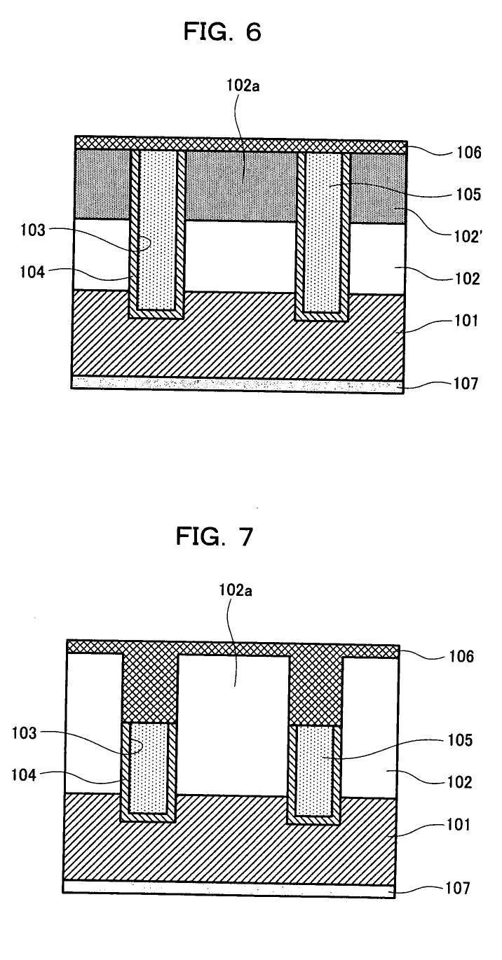

FIG. 6 is a sectional view showing another embodiment of the present invention. A lower semiconductor layer 102 having a lower impurity concentration than the semiconductor substrate 101 is formed on one of the major surfaces, that is, the front and back surfaces, of the semiconductor substrate 101. An upper semiconductor layer 102′ having a much lower impurity concentration is formed on the front surface of the lower semiconductor layer 102. At least one trench 103 is formed which extends from the front surface of the upper semiconductor layer 102′ to the semiconductor substrate 101. The mesa portion 102a is formed between the trenches 103 in both the lower and upper semiconductor layers 102 and 102′.

The insulating film 104 is formed at the boundary between the mesa portion 102a and each of the trenches 103. The first electrode 105 is formed inside the trench 103 surrounded by the insulating film 104. The second electrode 106 formed on the front surface of the low-concentration semiconductor layer 102′ so as to cover the first electrode 105 forms a Schottky junction with the upper semiconductor layer 102′ and an ohmic junction with the first electrode 105. The third electrode 107 is formed on the other of the major surfaces, that is, the front and back surfaces, of the semiconductor substrate 101.

Electric fields are applied so that the intensity of the electric fields inside the semiconductor layers 102 and 102′ is proportional to the concentration of impurities at appropriate positions in the layers. Thus, the concentration of impurities at the appropriate positions in the semiconductor layers 102 and 102′ is adjusted step by step to fix the breakdown voltages of the low-concentration semiconductor layers 102 and 102′.

In a specific example of the Schottky barrier semiconductor device, the material of the second electrode 106 is Ti, and the Schottky barrier has a height of 0.58 eV. The N-type (or P-type) semiconductor substrate 101 has an impurity concentration of 3×10¹⁹ cm⁻³. The concentration of impurities in the lower semiconductor layer 102 is 8×10¹⁶ cm⁻³ and the thickness is 2 um. The concentration of impurities in the upper semiconductor layer 102′ is 1×10¹⁶ cm⁻³ and the thickness is 1.5 um.

The impurity rising height to which impurities rise from the semiconductor substrate 101 when the semiconductor layer 102 is epitaxially formed is 2 um. The gradient of the concentration of impurities in the rising regions of the semiconductor layers 102 and 102′ is at most 1×10¹⁹ cm⁻⁴. The mesa portion 102a has a width of 2 um. The trench has a depth of 4 um. The insulating film 104 is a thermal oxide film having a thickness of 2000 Å. The first electrode 105 is N-type doped polysilicon.

As shown in FIG. 2C, in the present invention, the trench 103 reaches the semiconductor substrate 101, and the insulating film 104 abuts against the semiconductor substrate 101. Thus, the depletion region 201, lying around the periphery of the first electrode 105, is blocked by the semiconductor substrate 101 and thus discontinuously formed. The depletion region 201 is linearly shaped at the lower end of the trench 103.

Consequently, the depletion region 201 has no corners, that is, no elements at which electric fields concentrate. Thus, as in the case of Embodiment 1, the field intensity is distributed in the depletion region 201 around the periphery of the trench 103 without forming any rapid peak. Therefore, the semiconductor device in accordance with the present invention has a higher breakdown voltage, a smaller backward leakage current, and a smaller backward leakage current at the same forward voltage drop than the conventional semiconductor device. This improves the tradeoff relationship.

### Embodiment 3

FIG. 7 shows a sectional view of another embodiment of the present invention. In FIG. 7, the Schottky barrier semiconductor device has the semiconductor layer 102 with the low impurity concentration formed on one of the major surfaces, that is, the front and back surfaces, of the semiconductor substrate 101. The plurality of trenches 103 are formed in the low-concentration semiconductor layer 102. Each of the trenches 103 is shaped so as to extend from the front surface of the low-concentration semiconductor layer 102 to the semiconductor substrate 101.

The part of the semiconductor layer 102 between the trenches 103 forms the mesa portion 102a. The insulating film 104 is formed at the boundary between the mesa portion 102a and the trench 103. The first electrode 105 is formed inside the trench 103 surrounded by the insulating film 104.

The second electrode 106 formed on the front surface of the low-concentration semiconductor layer 102 so as to cover the first electrode 105 forms a Schottky junction with the semiconductor layer 102 and an ohmic junction with the first electrode 105. The third electrode 107 is formed on the other of the major surfaces, that is, the front and back surfaces, of the semiconductor substrate 101.

The second electrode 106 has a recessed and projecting shape with respect to the semiconductor layer 102, with the projecting portions projecting into the respective trenches 103. The insulating film 104 is formed so as to abut against the second electrode 106 in the middle of the trench 103. In this case, the length of a sidewall portion of the mesa portion 102a which is covered with the insulating film 104, that is, the distance from a position corresponding to the lower end position of the electrode 106 in the trench 103 to the semiconductor substrate 101, is designed to be proportional to a breakdown voltage required for the semiconductor device.

Electric fields are applied so that the intensity of the electric fields inside the semiconductor layer 102 is proportional to the concentration of impurities at appropriate positions in the layer. Thus, the concentration of impurities at the appropriate positions in the semiconductor layer 102 is adjusted to fix the breakdown voltages of the low-concentration semiconductor layer 102.

In a specific example of the Schottky barrier semiconductor device, the material of the second electrode 106 is Ti, and the Schottky barrier has a height of 0.58 eV. The N-type (or P-type) semiconductor substrate 101 has an impurity concentration of 3×10¹⁹ cm⁻³. The impurities in the low-concentration semiconductor layer 102 have a uniform concentration of 5×10¹⁵ cm⁻³ down to a depth of 1.5 um from the front surface of the semiconductor layer 102. The impurity rising height to which impurities rise from the semiconductor substrate 101 when the semiconductor layer 102 is epitaxially formed is 2 um. The gradient of the concentration of impurities in the rising regions of the semiconductor layer 102 is at most 1×10¹⁹ cm⁻⁴. The semiconductor layer 102 has a thickness of 3.5 um. The mesa portion 102a has a width of 2 um. The trench has a depth of 4 um. The insulating film 104 is a thermal oxide film having a thickness of 2000 Å. The sidewall of the mesa portion 102a which is covered with the insulating film 104 has a length of 2.5 um. The first electrode 105 is N-type doped polysilicon.

As shown in FIG. 2D, in the present invention, the trench 103 reaches the semiconductor substrate 101, and the insulating film 104 abuts against the semiconductor substrate 101. Thus, the depletion region 201, lying around the periphery of the first electrode 105, is blocked by the semiconductor substrate 101 and thus discontinuously formed. The depletion region 201 is linearly shaped at the lower end of the trench 103.

Consequently, the depletion region 201 has no corners, that is, no elements at which electric fields concentrate. Thus, as in the case of Embodiment 1, the field intensity is distributed in the depletion region 201 around the periphery of the trench 103 without forming any rapid peak.

Therefore, the semiconductor device in accordance with the present invention has a higher breakdown voltage and a smaller backward leakage current than the conventional semiconductor device.

Further, in Embodiment 3, the Schottky junction is provided on the sidewall of the mesa portion 102a. This enables an increase in the amount of forward current even with the chip size remaining unchanged. That is, as shown in FIG. 5, Embodiment 3 can reduce the forward voltage drop at the same backward current compared to Embodiments 1 and 2, described above.

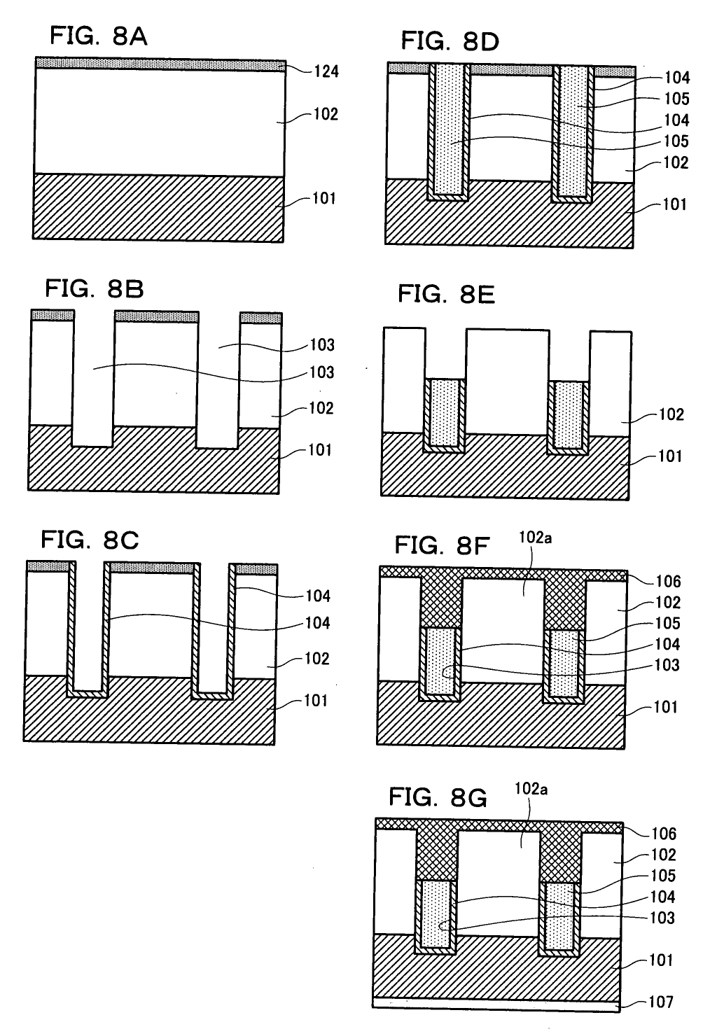

As shown in FIGS. 8A to 8G, a process of manufacturing a semiconductor device in accordance with the present embodiment includes an initial oxidizing step in FIG. 8A, a trench forming step in FIG. 8B, an insulating film forming step in FIG. 8C, a first electrode forming step in FIG. 8D, a Schottky interface exposing step in FIG. 8E, a second electrode forming step in FIG. 8F, and a third electrode forming step in FIG. 8G.

When the insulating film 104 is a silicon oxide film, a PSG (Phospho-Silicate-Glass) film is formed by CVD (Chemical Vapor Deposition). At this time, the PSG film is generated so that the concentration of phosphorous in the PSG film increases as the distance from the mesa portion 102a increases. The speed at which the PSG film is etched increases as the phosphorous concentration increases.

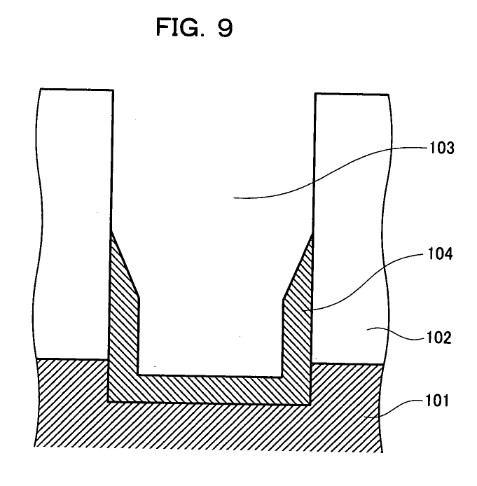

The phosphorous concentration of the PSG film can be adjusted so that when the interface on which the Schottky junction is to be formed is exposed by etching in the Schottky interface exposing step in FIG. 8E, the etching speed for the PSG film increases as the distance from the trench decreases. This enables the end of the insulating film 104 to be tapered as shown in FIG. 9.

The tapered end of the insulating film 104, which abuts against the second electrode 106, makes it possible to relax the concentration of electric fields in the vicinity of the end of the Schottky junction, that is, the lower end of the second electrode 106 projecting into the trench 103. This makes it possible to prevent an increase in backward leakage current and a reduction in surge resistance.

### Embodiment 4

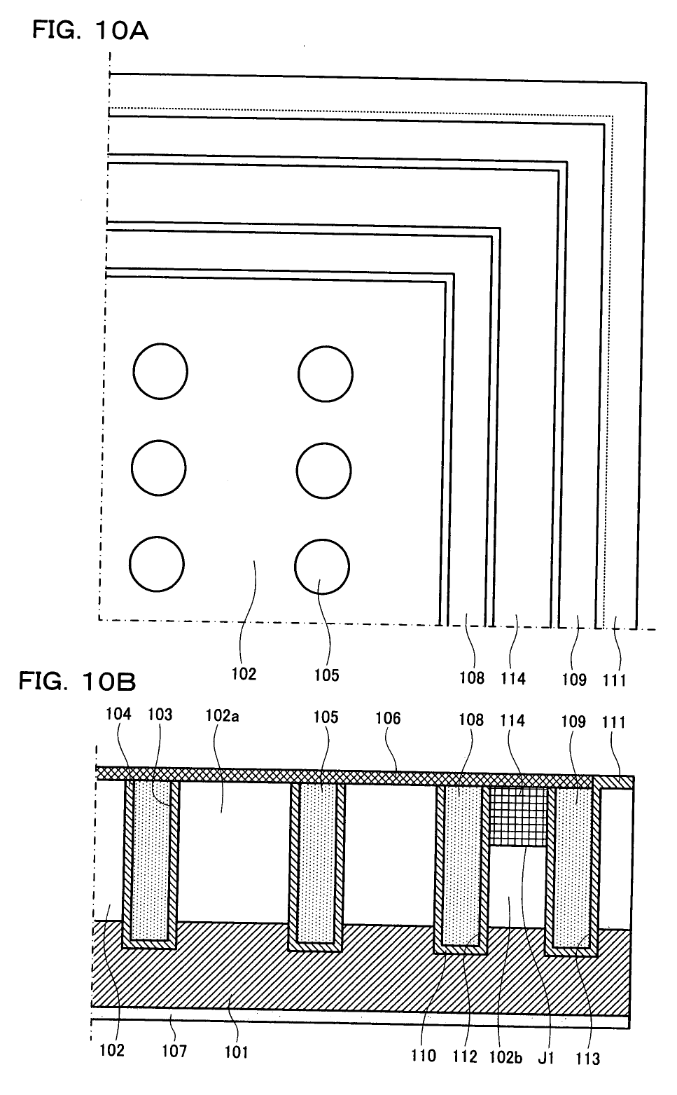

FIGS. 10A and 10B show sectional views of a Schottky barrier semiconductor device in accordance with another embodiment of the present invention. In FIGS. 10A and 10B, the Schottky barrier semiconductor device has the semiconductor layer 102 with the low impurity concentration formed on one of the major surfaces, that is, the front and back surfaces, of the semiconductor substrate 101. The plurality of trenches 103 are formed in the low-concentration semiconductor layer 102. Each of the trenches 103 is shaped so as to extend from the front surface of the low-concentration semiconductor layer 102 to the semiconductor substrate 101.

The part of the semiconductor layer 102 between the trenches 103 forms the mesa portion 102a. The insulating film 104 is formed at the boundary between the mesa portion 102a and the trench 103. The first electrode 105 is formed inside the trench 103 surrounded by the insulating film 104.

The second electrode 106 formed on the front surface of the low-concentration semiconductor layer 102 so as to cover the first electrode 105 forms a Schottky junction with the semiconductor layer 102 and an ohmic junction with the first electrode 105. The third electrode 107 is formed on the second major surface of the semiconductor substrate 101.

Electric fields are applied so that the intensity of the electric fields inside the semiconductor layer 102 is proportional to the concentration of impurities at appropriate positions in the layer. Thus, the concentration of impurities at the appropriate positions in the semiconductor layer 102 is adjusted to fix the breakdown voltages of the low-concentration semiconductor layer 102.

A first annular trench 108 is formed so as to surround all the mesa portions 102a and the trenches 103. A band-like mesa portion 102b is formed outside the first annular trench 108 so as to surround the outer periphery of the first annular trench 108. A second annular trench 109 is formed so as to surround the outer periphery of the band-like mesa portion 102b. The first annular trench 108 is parallel to the second annular trench 109.

An insulating film 110 is formed at the boundary between the first annular trench 108 and the semiconductor layer 102. An insulating film 111 is formed at the boundary between the second annular trench 109 and the semiconductor layer 102. A fourth electrode 112 is formed inside the first annular trench 108 surrounded by the insulating film 110. A fifth electrode 113 is formed inside the second annular trench 109 surrounded by the insulating film 111.

The outer band-like mesa portion 102b is made of the second semiconductor layer 114 on the semiconductor layer 102; the second semiconductor layer is made of a P-type semiconductor, and the semiconductor layer 102 is made of an N-type semiconductor. The outer band-like mesa portion 102b forms an ohmic junction between the surface of the second semiconductor layer 114 and each of the second, fourth, and fifth electrodes 106, 112, and 113.

Thus, in the outer band-like mesa portion 102b, the semiconductor layer 102, made of the N-type semiconductor, and the second semiconductor layer 114, made of the P-type semiconductor, form a PN junction J1. The breakdown voltage of the PN junction J1 is designed to be lower than that of the semiconductor layer 102 in the inner mesa portion 102a. The breakdown voltage of the semiconductor device is determined by the PN junction J1.

In a specific example of the Schottky barrier semiconductor device, the material of the second electrode 106 is Ti, and the Schottky barrier has a height of 0.58 eV. The N-type semiconductor substrate 101 has an impurity concentration of 3×10¹⁹ cm⁻³. The impurities in the low-concentration semiconductor layer 102 have a uniform concentration of 5×10¹⁵ cm⁻³ down to a depth of 1.5 um from the front surface of the semiconductor layer 102. The impurity rising height to which impurities rise from the semiconductor substrate 101 when the semiconductor layer 102 is epitaxially formed is 2 um. The gradient of the concentration of impurities in the rising regions of the semiconductor layer 102 is at most 1×10¹⁹ cm⁻⁴. The semiconductor layer 102 has a thickness of 3.5 um. The mesa portions 102a and 102b have a width of 2 um. The trench has a depth of 4 um. The insulating films 104, 108, and 109 are thermal oxide films having a thickness of 2000 Å. The first, fourth, and fifth electrodes 105, 112, and 113 are N-type doped polysilicon. The second semiconductor layer 114 has an impurity concentration of 1×10¹⁷ cm⁻³ and a diffusion depth of 1 um.

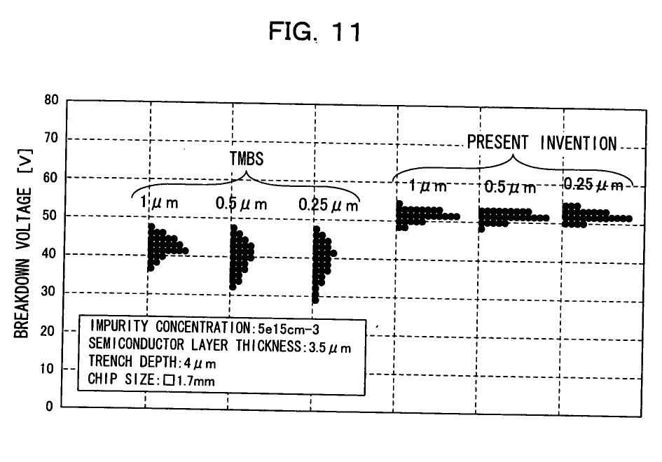

FIG. 11 shows a variation in breakdown voltage for the conventional TMBS and the present invention. For the TMBS, generally, the forward voltage drop and the backward leakage current can be reduced by reducing the sizes of the trench and mesa to allow as many trench/mesa structures as possible to be formed in one semiconductor element, in order to effectively utilize the area of the TMBS.

As described above, the breakdown voltage depends on the thickness of the insulating film on the trench, the shape of the trench bottom, and the profile of impurities in the semiconductor layer. A reduction in the size of the trench/mesa structure makes the breakdown voltage more dependent on variations in the above parameters. This results in an increased variation in breakdown voltage among the trench/mesa structures.

As described above, the breakdown voltage of the semiconductor device is equal to the minimum breakdown voltage of the trench/mesa structures. Thus, the variation in breakdown voltage increases as the size of the trench/mesa structure decreases. On the other hand, in the present invention, the breakdown voltage is determined by the PN junction J1, reducing the variation in breakdown voltage.

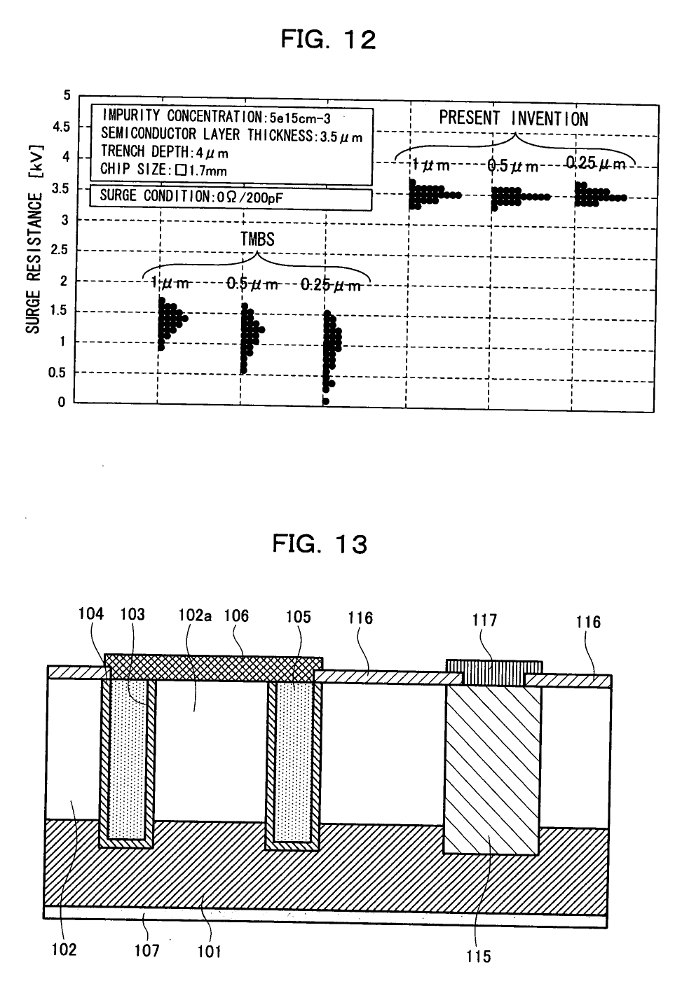

FIG. 12 shows the surge resistance for the TMBS and the present invention. As described above, an applied surge or transient voltage flows through a region in the semiconductor device which has the lowest breakdown voltage. In the prior art, the level of the variation in breakdown voltage among the trench/mesa portions increases as the size of the trench/mesa portion decreases. Thus, the surge current flows locally through the trench/mesa portion with the lowest breakdown voltage, further reducing the surge resistance of the trench/mesa portion. As a result, the conventional TMBS offers a very low surge resistance.

On the other hand, in the semiconductor device in accordance with the present invention, the surge current always flows through the PN junction J1. This enables the surge resistance to be maintained regardless of the size of the trench/mesa portion. Further, the surge resistance increases as the area of the PN junction J1 increases. This enables a reduction in the size of the trench/mesa portion and in forward voltage drop and backward leakage current as well as an increase in surge resistance.

### Embodiment 5

FIG. 13 shows another embodiment of the present invention. In FIG. 13, the Schottky barrier semiconductor device has the semiconductor layer 102 with the low impurity concentration formed on one of the major surfaces, that is, the front and back surfaces, of the semiconductor substrate 101. The plurality of trenches 103 are formed in the low-concentration semiconductor layer 102. Each of the trenches 103 is shaped so as to extend from the front surface of the low-concentration semiconductor layer 102 to the semiconductor substrate 101.

The part of the semiconductor layer 102 between the trenches 103 forms the mesa portion 102a. The insulating film 104 is formed at the boundary between the mesa portion 102a and the trench 103. The first electrode 105 is formed inside the trench 103 surrounded by the insulating film 104.

The second electrode 106 formed on the front surface of the low-concentration semiconductor layer 102 so as to cover the first electrode 105 forms a Schottky junction with the semiconductor layer 102 and an ohmic junction with the first electrode 105. The third electrode 107 is formed on the other of the major surfaces, that is, the front and back surfaces, of the semiconductor substrate 101.

A semiconductor layer 115 with a high impurity concentration is formed at a predetermined position in the low-concentration semiconductor layer 102. The semiconductor layer 115 is shaped so as to extend from the front surface of the low-concentration semiconductor layer 102 to the semiconductor substrate 101. An insulating film 116 is formed over the low-concentration semiconductor layer 102 and the high-concentration semiconductor layer 115. A window is formed in the insulating film 116 at a position corresponding to the front surface of the high-concentration semiconductor layer 115. The insulating film 116 is also coupled to the insulating film 104. A sixth electrode 117 is formed over the window in the high-concentration semiconductor layer 115.

The above semiconductor device is of a flip chip type having an anode and a cathode on a front surface of the low-concentration first semiconductor layer 102. The flip chip type enables a sharp reduction in mounting area.

### Embodiment 6

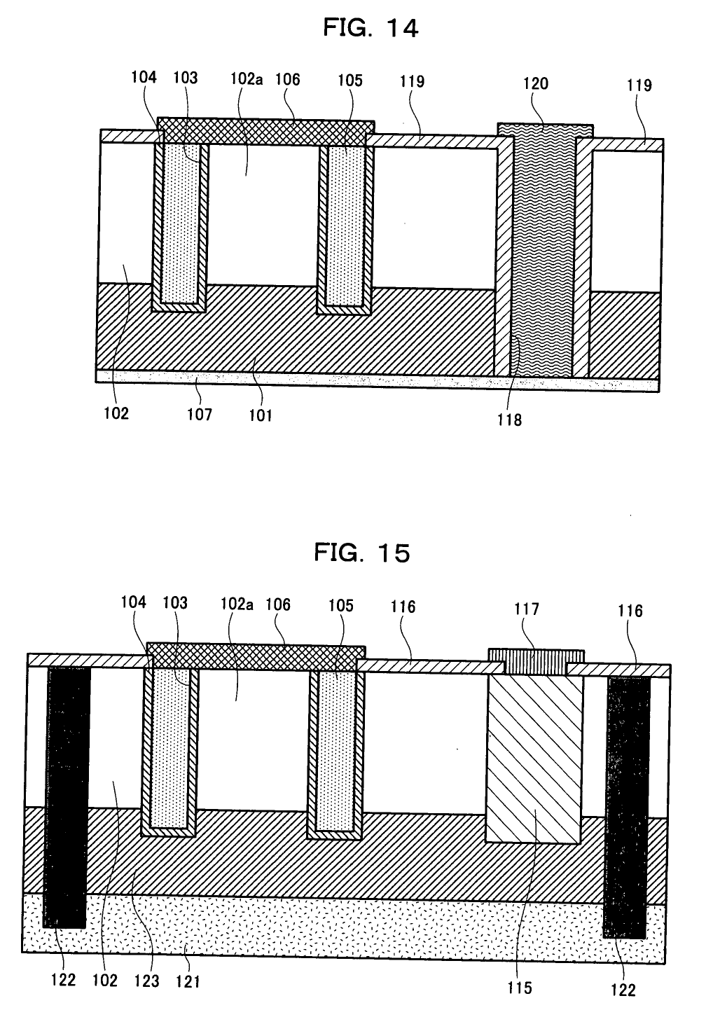

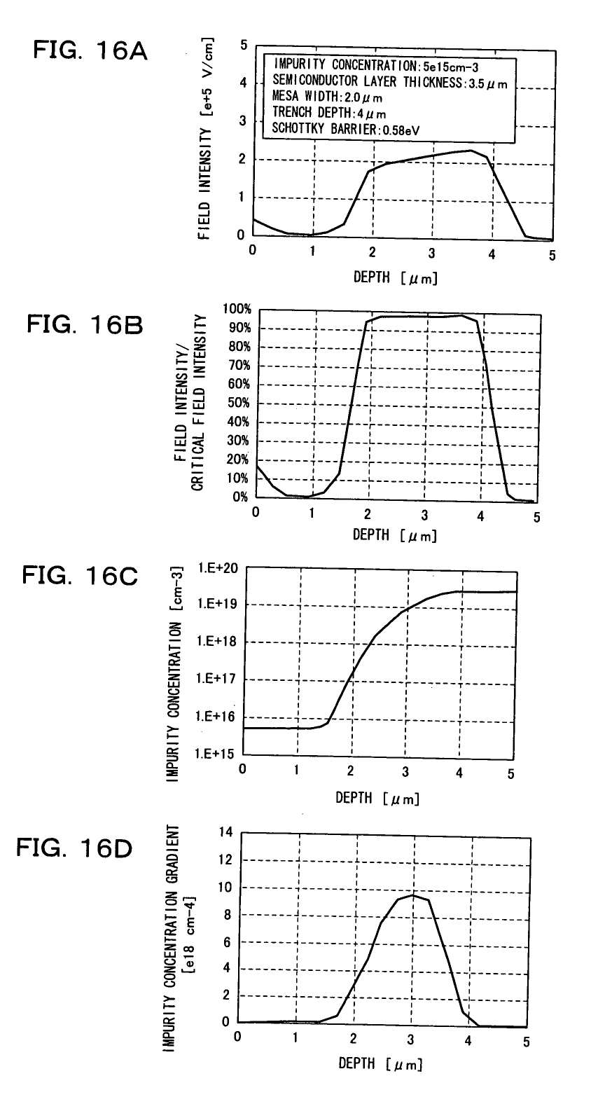

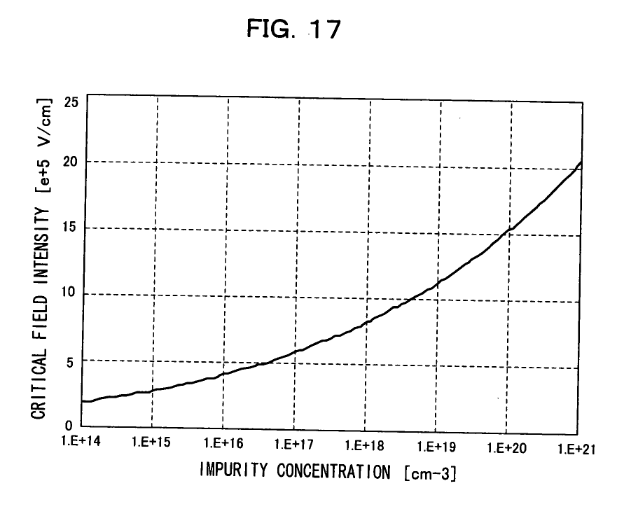

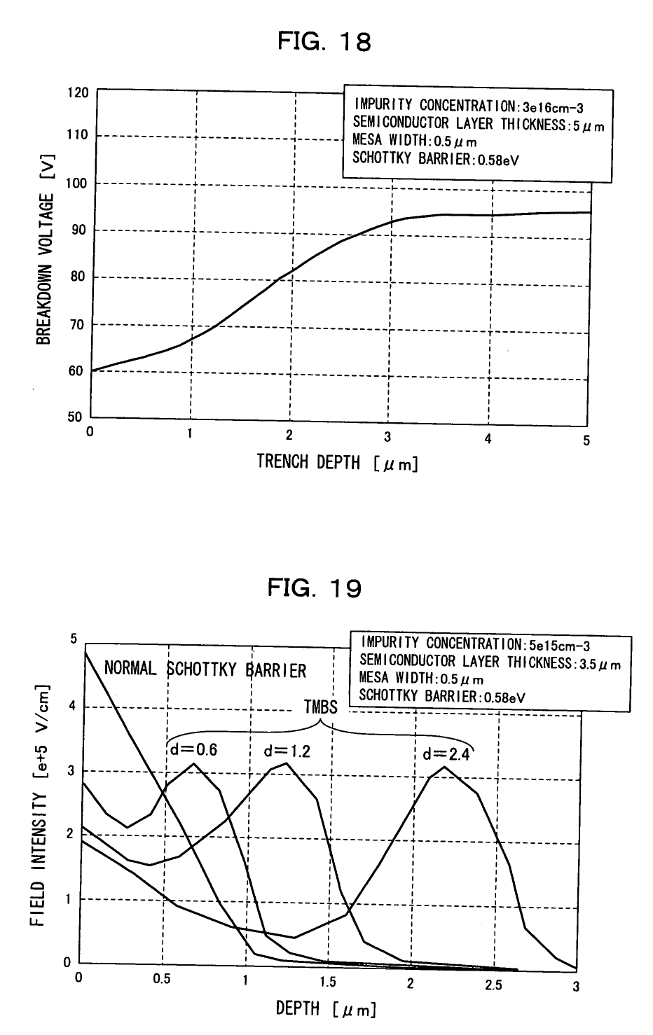

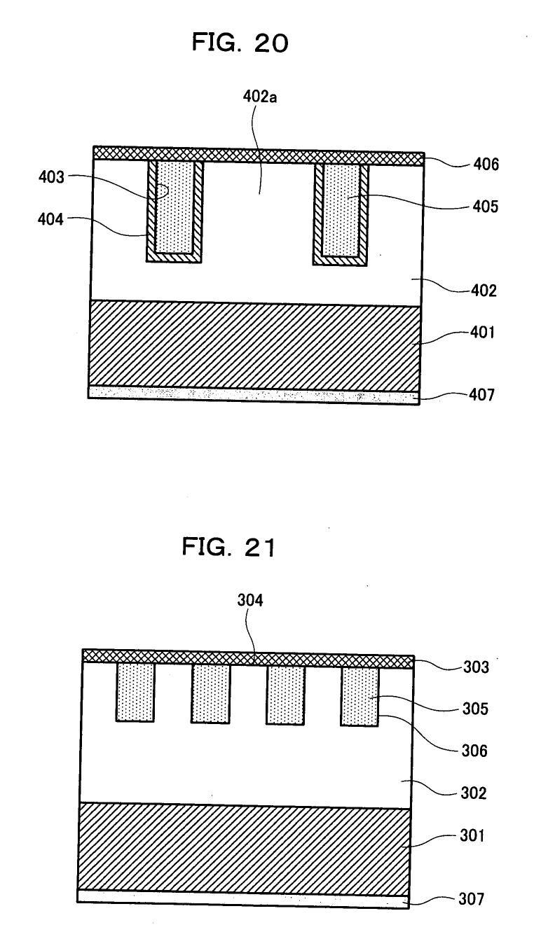

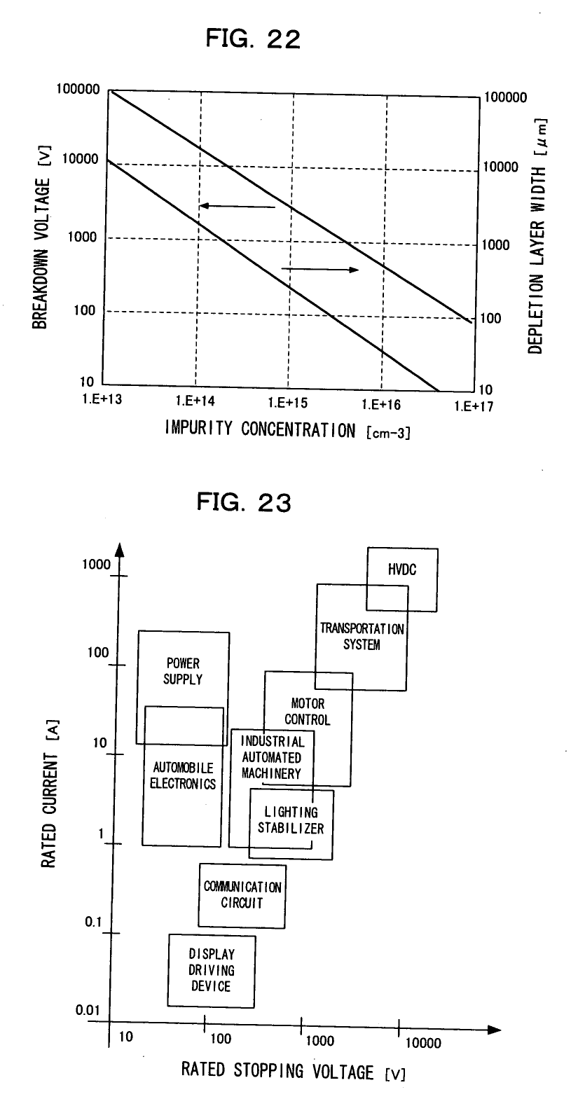

FIG. 14 shows another embodiment of the present invention. In FIG. 14, the Schottky barrier semiconductor device has the semiconductor layer 102 with the low impurity concentration formed on one of the major surfaces, that is, the front and back surfaces, of the semiconductor substrate 101. The plurality of trenches 103 are formed in the low-concentration semiconductor layer 102. Each of the trenches 103 is shaped so as to extend from the front surface of the low-concentration semiconductor layer 102 to the semiconductor substrate 101.

The part of the semiconductor layer 102 between the trenches 103 forms the mesa portion 102a. The insulating film 104 is formed at the boundary between the mesa portion 102a and the trench 103. The first electrode 105 is formed inside the trench 103 surrounded by the insulating film 104.

The second electrode 106 formed on the front surface of the low-concentration semiconductor layer 102 so as to cover the first electrode 105 forms a Schottky junction with the semiconductor layer 102 and an ohmic junction with the first electrode 105. The third electrode 107 is formed on the other of the major surfaces, that is, the front and back surfaces, of the semiconductor substrate 101.

A through-hole 118 is formed so as to extend from the front surface of the low-concentration semiconductor layer 102 to the other major surface of the semiconductor substrate 101. An insulating film 119 is formed on a side surface of the through-hole 118 and on the front surface of the low-concentration semiconductor layer 102. The insulating film 119 is coupled to the insulating film 104 on the trench 103. A seventh electrode 120 is formed in the through-hole 118 and forms an ohmic junction with the third electrode 107, formed on the other major surface of the semiconductor substrate 101.

The above semiconductor device is of a flip chip type having an anode and a cathode on a front surface of the low-concentration first semiconductor layer 102. The flip chip type enables a sharp reduction in mounting area.

### Embodiment 7

FIG. 15 shows another embodiment of the present invention. In FIG. 15, on an N or P conductivity type semiconductor substrate (in this case, the P type) 121, a lower semiconductor layer of a different conductivity type (in this case, the N type) 123 is formed. On the lower semiconductor layer 123, a low-concentration upper semiconductor layer of the same conductivity type (in this case, the N type) 102 is formed.

A high-concentration semiconductor separation layer (in this case, the P type) 122 is formed so as to extend from the front surface of the low-concentration semiconductor layer 102 to the semiconductor substrate 121. The plurality of trenches 103 are formed so as to extend from the front surface of the upper low-concentration semiconductor layer 102 to the lower semiconductor layer 123. The mesa portion 102a is formed between the trenches 103 in the low-concentration semiconductor layer 102. The insulating film 104 is formed at the boundary between the mesa portion 102a and the trench 103. The first electrode 105 is formed inside the trench 103 surrounded by the insulating film 104.

The second electrode 106 is formed on the front surface of the low-concentration semiconductor layer 102 so as to cover the first electrode 105. The semiconductor layer 102 thus forms a Schottky junction with the second electrode 106. The first electrode 105 forms an ohmic junction with the second electrode 106.

The high-concentration semiconductor layer (in this case, the N type) 115 is formed so as to extend from the front surface of the upper low-concentration semiconductor layer 102 to the lower semiconductor layer 123. A window is formed in the high-concentration semiconductor layer 115. The insulating film 116 is formed which is coupled to the insulating film 104. The sixth electrode 117 is formed over the window in the high-concentration semiconductor layer 115.

The present embodiment may be a semiconductor integrated device having a power supply IC and a rectifier both used for a DC-DC power supply and formed into one chip. This provides a highly integrated circuit.

### Embodiment 8

In the method of manufacturing the Schottky barrier semiconductor device in accordance with the present invention, the low-concentration semiconductor layer 102 is formed on the semiconductor substrate 101 by epitaxial growth. Arsenic is used as N-type impurities for the semiconductor substrate 101. The arsenic reduces the resistance of the semiconductor substrate 101 and thus the forward voltage drop. The concentration of impurities in the epitaxial growth layer in the arsenic substrate varies significantly. Accordingly, a monosilane gas is used for the epitaxial growth at a lower temperature between 900 and 1,000° C. This makes it possible to prevent diffusion to the epitaxial growth layer of arsenic, that is, the low-concentration semiconductor layer 102. This in turn allows a reduction in the variation in the impurity concentration in the low-concentration semiconductor layer 102. Thus, the concentration gradient of impurities in the low-concentration semiconductor layer 102 can be optimized to maximize the breakdown voltage.

With the method of manufacturing the semiconductor device in accordance with the present invention, elements other than those described above can be manufactured by the conventional manufacturing method. Thus, the description of a method of manufacturing the other elements is omitted.

The Schottky barrier semiconductor device in accordance with the present invention is used as a rectifier in a power supply circuit. The Schottky barrier semiconductor device in accordance with the present invention is efficient because of the reduced backward leakage current, the increased stopping voltage, the reduced forward voltage drop, and the improved high power efficiency, and has a high durability against the surge and transient voltage. The Schottky barrier semiconductor device in accordance with the present invention thus makes it possible to reduce the voltage of the power supply circuit and to improve efficiency and reliability.

What is claimed is:

1. A semiconductor device comprising a semiconductor substrate, a semiconductor layer formed on one major surface of the semiconductor substrate and having a lower impurity concentration than the semiconductor substrate, a plurality of trenches formed in the semiconductor layer so as to extend from a front surface of the layer to the semiconductor substrate, a mesa portion formed between the trenches in the semiconductor layer, an insulating film formed at a boundary between the mesa portion and the trench, a first electrode formed inside the trench surrounded by the insulating film, a second electrode formed on the front surface of the semiconductor layer so as to cover the first electrode and forming a Schottky junction with the semiconductor layer and an ohmic junction with the first electrode, and a third electrode formed on the other major surface of the semiconductor substrate.

2. The semiconductor device according to claim 1, wherein the impurity concentration is adjusted at appropriate positions in the semiconductor layer to adjust the intensity of electric fields in the semiconductor layer which is proportional to the impurity concentration, and a breakdown voltage in the semiconductor layer is fixed.

3. The semiconductor device according to claim 1, wherein the concentration gradient of the impurities in the semiconductor layer varies step by step and increases as the distance from the semiconductor substrate decreases, and the breakdown voltage in the semiconductor layer is fixed.

4. The semiconductor device according to claim 1, wherein the concentration of impurities in the semiconductor layer is substantially fixed in a region extending at least 1 um from a Schottky junction interface between the second electrode and the semiconductor layer, to the semiconductor substrate.

5. The semiconductor device according to claim 1, wherein a depletion region formed around a periphery of the first electrode in the semiconductor layer covers the mesa portion all over the width of the mesa portion between the trenches.

6. The semiconductor device according to claim 1, wherein a pair of parallel annular trenches surrounding all the mesa portions and all the trenches is formed in the semiconductor layer, and a portion between the annular trenches constitutes a band-like mesa portion, wherein a band-like insulating film is formed along a boundary between each of the annular trenches and the semiconductor layer, a fourth electrode is formed in one of the annular trenches, and a fifth electrode is formed in the other annular trench, wherein the band-like mesa portion is made of the semiconductor layer constituting a lower layer portion and a semiconductor layer constituting an upper layer portion and having a conductivity type different from that of the semiconductor layer, and the second electrode forms an ohmic junction with the upper semiconductor layer and with the first, fourth, and fifth electrodes, and wherein the breakdown voltage at a PN junction between the upper semiconductor layer and lower semiconductor layer of the band-like mesa portion determines the breakdown voltage of the semiconductor device.

7. The semiconductor device according to claim 6, wherein the depletion region formed around the periphery of the fourth and fifth electrodes in the semiconductor layer covers the band-like mesa portion all over the width of the mesa portion between the annular trenches.

8. The semiconductor device according to claim 1, wherein the second electrode has a recessed and projecting shape at the interface between the second electrode and the semiconductor layer.

9. The semiconductor device according to claim 8, wherein the second electrode projects partly into the trench, inside which the insulating film abuts against the second electrode, and the Schottky junction between the semiconductor layer and the second electrode is formed around the periphery of the trench.

10. The semiconductor device according to claim 9, wherein a terminal portion of the insulating film which abuts against the second electrode inside the trench is tapered.

11. The semiconductor device according to claim 1, wherein a high-concentration semiconductor layer is formed so as to extend from the front surface of the low-concentration semiconductor layer to the semiconductor substrate, and an insulating film in a front surface portion is formed over the front surfaces of the low-concentration semiconductor layer and the high-concentration semiconductor layer so as to join to the insulating film at the boundary between the trench and the semiconductor layer, and wherein a window is formed in the insulating film in the front surface portion located on the front surface of the high-concentration semiconductor layer, and a sixth electrode is formed over the window in the high-concentration semiconductor layer.

12. The semiconductor device according to claim 1, wherein a seventh electrode is formed so as to extend from the front surface of the low-concentration semiconductor layer to the other major surface of the semiconductor substrate, an insulating film is formed at an electrode boundary between the seventh electrode and the low-concentration semiconductor layer and at an electrode boundary between the seventh electrode and the semiconductor substrate, and the seventh electrode and the third electrode form an ohmic junction.

13. The semiconductor device according to claim 11, wherein a high-concentration semiconductor layer is formed between the semiconductor substrate and the low-concentration semiconductor layer, and a high-concentration semiconductor separation layer is formed so as to extend from the front surface of the low-concentration semiconductor layer to the semiconductor substrate, and wherein the low-concentration semiconductor layer and the high-concentration semiconductor layer formed between the semiconductor substrate and the low-concentration semiconductor layer have a conductivity type different from that of the semiconductor substrate, and the semiconductor separation layer has the same conductivity type as that of the semiconductor substrate.
